(19) United States
(12) Patent Application Publication
(10) Pub. No.: US 2006/0205232 A1
(43) Pub. Date: Sep. 14, 2006

(54) Film treatment method preventing blocked etch of low-K dielectrics

(76) Inventors: Lih-Ping Li, Hsinchu (TW); Tzong-Sheng Chang, Hsin-Chu (TW); William Kuo, Hsin-Chu (TW); Tsung-Hsien Lee, Hsin-Chu (TW); Chun-Lin Tsai, Hsin-Chu (TW); Szu-An Wu, Hsin-Chu (TW); Yin-Ping Lee, Kaohsiung (TW)

Correspondence Address: DUANE MORRIS, LLP;IP DEPARTMENT, 30 SOUTH 17TH STREET, PHILADELPHIA, PA, 19103-4196, US

(21) Appl. No.: 11/076,702

(22) Filed: Mar. 10, 2005

(51) Int. Cl. H01L 21/31; H01L 21/469

(52) U.S. Cl. 438/778

(57) ABSTRACT

A method for etching a dielectric material in a semiconductor device is disclosed. After providing a conductive region, a dielectric layer is formed over the conductive region. A dielectric antireflective coating (DARC) layer is further formed on the dielectric layer. Then, a moisture-removal step is performed that removes moisture from the DARC layer and from an interface region between the dielectric and the DARC layer. A masking pattern is transferred into the DARC layer and the dielectric layer.

### BACKGROUND

The present invention relates generally to integrated circuit designs, and more particularly to methods to relax the short queue time typically required between low-K dielectric processes.

An integrated circuit (IC) can be produced with metallization and interlevel dielectrics that are planarized by chemical-mechanical-polishing (CMP). Above each metal level, typically, an etch-stop layer is deposited thereon, and serves two purposes. The first purpose is to act as a barrier to the diffusion of a particular metal layer into the next level of dielectric layer, whether the dielectric layer is a typical oxide or a specialized low-K dielectric layer. The second purpose is to provide an etch-stop layer for the via etch that may be designed to come down to the particular metal layer. Without the etch-stop layer, the succeeding via etch would, in some areas, have time to attack the particular metal layer before all of the deep vias are evenly etched to completion.

In order to maximize circuit speed, low-K dielectrics are used between metal layers. A lower dielectric constant “K” means a lower capacitance between two metal layers. This lower capacitance allows faster signal propagation between components within an IC, thereby increasing overall IC performance. However, the low-K dielectrics available in the market today are specialized materials with side effects. For example, if a photoresist is coated directly on a low-K dielectric layer, it is possible that too much light used for a photolithography exposure is reflected by the interface region between the photoresist and the low-K dielectric layer. This reflection distorts the photolithography result, which can deviate significantly from an intended, designed image provided by the photoresist. To counter this problem, a dielectric antireflective coating (DARC) layer, typically silicon oxycarbide, is deposited on the low-K dielectric layer before the photoresist is coated. While the DARC layer improves optical performance, it also has other side effects. As an example, the DARC layer is permeable to, and absorbs from the atmosphere, moisture. Moisture is typically present even in advanced semiconductor processing, as moisture is introduced into the atmosphere of a semiconductor fabrication plant to limit static electricity. During intervals in normal production, the DARC layer absorbs moisture, which typically gathers at the interface region between the DARC layer and the low-K dielectric layer. When the interface region is moist, it becomes electrically conductive, thereby allowing electric charge to easily leak away and preventing such a charge from building up. Since a robust build-up of electric charge is necessary to attract gas ions from an etchant gas during dry etching, a reduced amount thereof significantly slows down the etching process.

Furthermore, a reduced amount of this electric charge causes etch non-uniformity across the wafer. For example, charge leakage at an isolated via window is different from the charge leakage at a cluster of via windows. This difference causes the etching voltage to be different, and in turn causes the etch rate at the isolated via window to be different from the etch rate at the cluster of via windows. When etch rates are different, via etching may be uneven or even incomplete across the IC wafer. This unevenness and incompleteness are typical reasons why ICs fail. Therefore, it is of paramount importance to increase etch rate and etch uniformity by reducing lateral electrical leakage at the interface region between the DARC layer and the low-K dielectric layer.

Desirable in the art of integrated circuit designs are additional methods for reducing moisture absorption by DARC materials and methods that relax the short queue time required between low-K dielectric processes to restrict such moisture absorption.

### SUMMARY

In view of the foregoing, the following provides a method for etching a dielectric material in a semiconductor device is disclosed. After providing a conductive region, a dielectric layer is formed over the conductive region. A dielectric antireflective coating (DARC) layer is further formed on the dielectric layer. Then, a moisture-removal step is performed that removes moisture from the DARC layer and from an interface region between the dielectric and the DARC layer. A masking pattern is transferred into the DARC layer and the dielectric layer.

The moisture-removal step may include vacuum baking the interface region at a predetermined temperature for a predetermined treatment period, UV curing, hot plate curing, or one or more plasma treatments using various plasma species. The plasma treatments may take place in a reaction chamber also used to deposit the DARC layer and/or the dielectric such as the low-K dielectric prior to other photoresist processes.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 illustrates a cross section of an IC in a production process with a low-K dielectric layer.

FIG. 2 illustrates a cross section of an IC in a production process with various successfully etched vias in accordance with one embodiment of the present invention.

FIG. 3 presents a flow chart of a modified production process in accordance with one embodiment of the present invention.

### DESCRIPTION

For illustration purposes, the following will provide a detailed description of a method that relaxes a queue time between low-K dielectric processes and improves etch rate and etch uniformity in low-K dielectrics. It is understood that the similar process may be applied to other types of dielectrics for manufacturing the semiconductor devices.

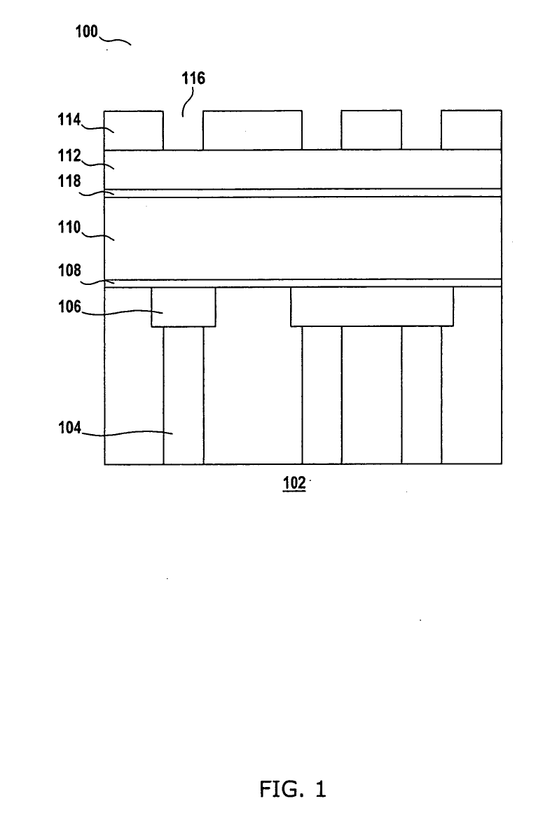

FIG. 1 illustrates a cross section 100 of an integrated circuit (IC) in a production process with a low-K dielectric layer. The cross section 100 shows a semiconductor substrate 102 at a production stage with first level metal completed, including a metal filled via 104 and a metal filled trench 106. The combination of the first level metal and its surrounding dielectrics may be seen as a conductor region. The metal is preferably copper or copper alloy, although other metals may be used. An etch-stop layer 108, preferably silicon carbide (SiC), is then deposited. This layer acts to prevent the diffusion of metal into succeeding dielectric layers, and acts as an etch-stop layer for subsequent via etch process steps.

A low-K dielectric layer 110 with a low dielectric constant, K, is deposited on top of this etch-stop layer 108. The low-K dielectric layer 110 can be organic or carbon-doped silicon oxide, and can be porous, with a dielectric constant less than about 3.4. The low-K dielectric layer 110 is beneficial in an IC since it reduces the capacitance between metal layers. The low-K dielectric layer 110 can, however, be difficult to pattern in photolithography since it tends to be very reflective. If a photoresist is deposited directly on the low-K dielectric layer 110, the patterning through the photoresist can be difficult since light will be reflected back into the photoresist, thereby reducing the quality of the printed image. Therefore, a dielectric anti-reflective coating (DARC) layer 112, preferably silicon oxycarbide (SiOC), is first deposited on the low-K dielectric layer 110. With the DARC layer 112, a photoresist 114 that is deposited thereon can be patterned to provide a suitably high image quality.

However, the use of the low-K dielectric layer 110 and the DARC layer 112 introduces another new difficulty into the process. The DARC layer 112 is permeable to moisture. Before the photoresist 114 is deposited, moisture may have penetrated into and through the DARC layer 112. A semi-isolated via window pattern 116 that is developed in the photoresist allows that pattern to be etched into the DARC layer 112 and further into the low-K dielectric layer 110 by dry etching. However, dry etching requires a significant voltage drop between the low pressure plasma above the IC and the layer of the IC that is being etched. An interface region 118 between the DARC layer 112 and the low-K dielectric layer 110 may collect moisture and become electrically conductive if moisture is not removed, such as provided by the present invention. The electrically conductive interface region 118 leaks away the charge build-up that is necessary to sustain the voltage that is required for dry etching.

A cluster of via windows will collect charge from the plasma of the dry etch process faster than it is leaked away by the surrounding interface region 118, which is electrically conductive. In an isolated or semi-isolated via window pattern 116, leakage outruns charge build-up in that case. The result is a lower voltage drop between the plasma and the layer being etched, and therefore, a slower etch rate. Therefore, an under-etched via pattern is produced in the DARC layer 112 if moisture is not removed, such as provided by the present invention. In such a scenario, electrical continuity cannot be completed to the lower metal layer, thereby causing the IC to fail.

Previous efforts to deal with the effects of moisture penetration simply necessitate a small time window between the deposition of the DARC layer and subsequent photoresist processing. While a small time window allows less moisture to penetrate through the DARC layer into the interface region, the ability to adequately control process reliability during that small time window is very limited.

In this invention, the time window between the deposition of the DARC layer and subsequent photoresist processing can be relaxed by treating the IC wafer with one or more of a plurality of processes after DARC layer 112 is formed, thereby removing moisture accumulated in DARC layer 112 and at the interface region 118 between the DARC layer 112 and the low-K dielectric layer 110. For example, a thermal treatment, such as vacuum baking the IC wafer at 300° C. for 30 minutes, may be used to remove moisture. The moisture that makes the interface region 118 electrically conductive is thus driven out, thereby allowing the state of the IC wafer to be close to what it has been immediately after the deposition of the DARC layer. At the moisture-removal process, photoresist processing and dry etching may advantageously take place as quickly as is practical but it can be seen that the queue time between the deposition of the DARC layer and subsequent photoresist processing can be relaxed without affecting etch quality.

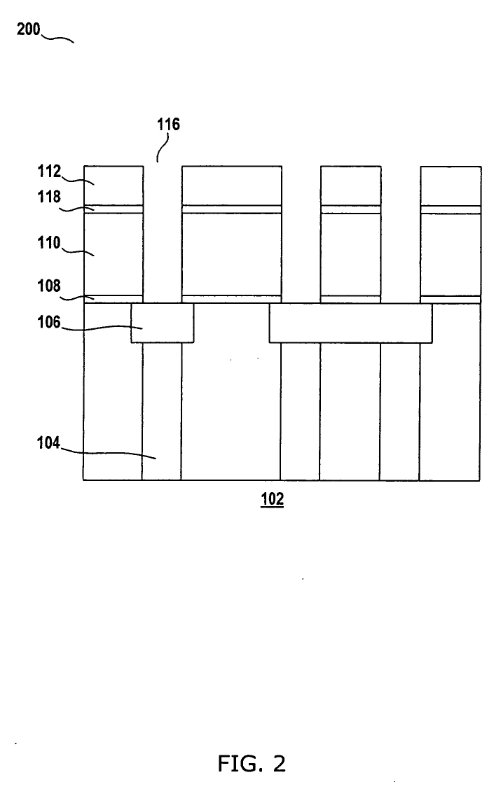

FIG. 2 illustrates a cross section 200 of an IC in a production process with various successfully etched vias in accordance with one embodiment of the present invention. The cross section 200 shows a semiconductor substrate 102 at a production stage with first level metal completed, including the metal filled via 104 and the metal filled trench 106. The etch-stop layer 108, the low-K dielectric layer 110, the DARC layer 112 and the interface region 118 remain the same, except that parts thereof have been dry etched away. The photoresist 114, no longer shown, has been removed. The semi-isolated via window pattern 116 is the same as in FIG.1. The difference is that the interface region 118 between the DARC layer 112 and the low-K dielectric layer 110 is dried by a plurality of processes, such as a vacuum bake, which reduces the electrical conductivity of the interface region 118 and allows the voltage to maintain at a level necessary for dry etching. The via etch continues until the etch in all vias has been completed down to the etch-stop layer 108. The etch-stop layer 108 is further etched away in a separate step.

Because the metal in the metal filled trench 106 is evenly and completely exposed for the establishment of electrical continuity with the next layer of metal to be filled in the etched cavity, electrical continuity can be established fully and completely.

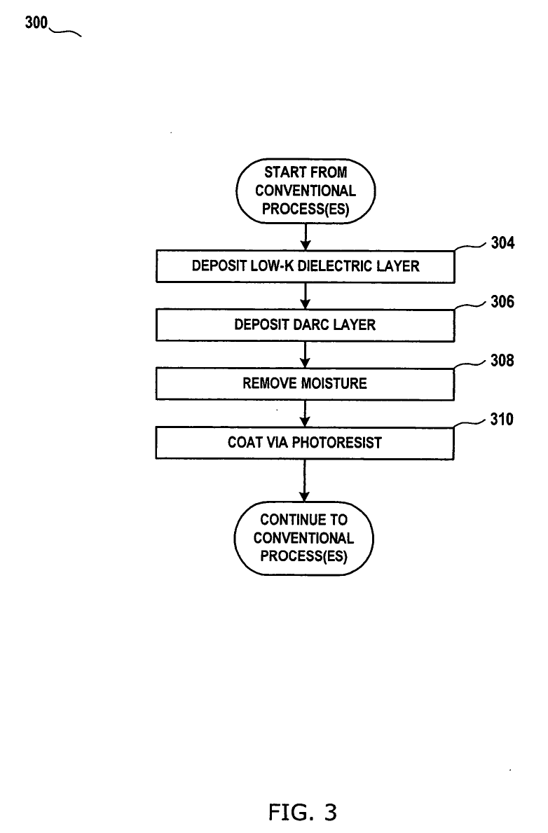

FIG. 3 presents a flow chart 300 of a modified production process in accordance with one embodiment of the present invention. The flow chart 300 starts after at least one conventional run of CMP planarization. In step 304, a low-K dielectric layer 110 is deposited. In step 306, a DARC layer 112, such as silicon oxycarbide, is deposited. Up to this point, only conventional processing steps are used. In step 308, a conventional production process is modified to include a process whereby moisture is removed. In one embodiment, the moisture-removal process may be a vacuum bake at 300° C. for 30 minutes that drives out the moisture that may be present in the DARC layer and/or at the interface region between the DARC layer and the low-K dielectric layer. It is understood that different temperatures and baking times, or different thermal-related processes may be used to ensure that enough moisture is driven out to prevent slow and non-uniform etching. For example, thermal treating can be performed with a bake at 200 to 400° C., or can be performed with ultraviolet light curing, or by hot plate curing, all of which may include a time ranging from 2 to 60 minutes. Thermal treating can also be performed with a bake at 400 to 700° C., by rapid thermal processing that may include a time of from 1 to 60 seconds. It is further understood that a predetermined pressure may also be used in this step. It is further understood that the DARC layer can be nitrogen-free, can be silicon oxynitride, or can be a carbon-containing material.

In another exemplary embodiment, the moisture-removal process in step 308 may be a plasma treatment, which also removes the moisture accumulated in the interface region and/or in the DARC layer. For example, the plasma treatment gas can be an inert gas plasma such as Argon or Helium plasma. In another example, the plasma treatment gas can be an oxygen-containing plasma such as ozone plasma. In yet another example, the plasma treatment gas can be a hydrogen-containing plasma such as hydrogen (H₂) or ammonia (NH₃) plasma.

The plasma treatment may advantageously be performed in a reaction chamber prior to other photoresist processes. The plasma treatment may take place, in-situ, in the same reaction chamber in which the low-K dielectric the DARC layer, or both, are formed. In this example, a reaction chamber is provided, wherein the low-K dielectric layer is first formed. A DARC layer may then be formed thereon in the same reaction chamber. Finally, the plasma treatment occurs in the reaction chamber to ensure that moisture is removed. Any of the aforementioned exemplary plasma treatments may be used as the in-situ plasma treatment.

After a moisture-removal process, a photoresist is coated and patterned in step 310 in preparation for via etching. After the step 310, conventional processing steps can be used to complete the production process. In this embodiment, the via windows are etched evenly and completely due to the vacuum bake in step 308 prior to the coating of a photoresist in step 310.

The above illustration provides many different embodiments or embodiments for implementing different features of the invention. Specific embodiments of components and processes are described to help clarify the invention. These are, of course, merely embodiments and are not intended to limit the invention from that described in the claims.

Although the invention is illustrated and described herein as embodied in one or more specific examples, it is nevertheless not intended to be limited to the details shown, since various modifications and structural changes may be made therein without departing from the spirit of the invention and within the scope and range of equivalents of the claims. Accordingly, it is appropriate that the appended claims be construed broadly and in a manner consistent with the scope of the invention, as set forth in the following claims.

What is claimed is:

1. A method for etching a dielectric material in a semiconductor device, comprising:
providing a conductive region;
forming a dielectric layer over the conductive region, and forming a dielectric antireflective coating (DARC) layer on the dielectric layer;
performing a moisture-removal step that removes moisture from the DARC layer and from an interface region between the dielectric and the DARC layer; and
transferring a masking pattern into the DARC layer and the dielectric layer.

2. The method of claim 1 wherein the dielectric layer comprises a low-K dielectric.

3. The method of claim 2 wherein the low-K dielectric layer is a carbon-doped silicon oxide, an organic low-K dielectric with a dielectric constant less than about 3.4, or a porous low-K dielectric having a dielectric constant less than about 3.4.

4. The method of claim 1 wherein the DARC layer is a nitrogen-free dielectric, a silicon oxynitride or a carbon-containing material having dielectric properties.

5. The method of claim 1 wherein the moisture-removal step is a thermal treatment step having a temperature within a range of 200 to 400° C. and a time within a range of 2 to 60 minutes.

6. The method of claim 1 wherein the moisture-removal step is a rapid thermal processing operation having a temperature within a range of 400 to 700° C. and a time within a range of 1 to 60 seconds.

7. The method of claim 1 wherein the moisture-removal step is a plasma treatment operation.

8. The method of claim 7 wherein the plasma treatment operation includes argon, helium or a further inert gas.

9. The method of claim 7 wherein the plasma treatment operation includes an ozone plasma or a further oxygen-containing plasma.

10. The method of claim 7 wherein the plasma treatment operation includes an ammonia plasma, a hydrogen plasma or a further hydrogen-containing plasma.

11. The method of claim 1 wherein the moisture-removal step comprises hot plate curing or ultraviolet light curing.

12. The method of claim 1 wherein the moisture-removal step is a plasma treatment operation that takes place in a reaction chamber further used for at least one of the forming of a dielectric layer and the forming of a DARC layer.

13. The method of claim 1 wherein the moisture-removal step is a vacuum bake.

14. The method of claim 1 wherein the transferring a masking pattern into the DARC layer and the dielectric layer includes forming an opening that exposes the conductive region.

15. A method for etching a dielectric material in a semiconductor device, comprising:
providing a conductive region;
forming a low-K dielectric layer over the conductive region, and a further dielectric layer on the low-K dielectric layer;
performing a moisture-removal step that removes moisture from said further dielectric layer and from an interface region between the low-K and the further dielectric layers; and
transferring a masking pattern into the low-K and the further dielectric layers.

16. The method of claim 15 wherein the conductive region comprises copper, a copper alloy, a metal silicide or polysilicon and the transferring a masking pattern into the DARC layer and the dielectric layer includes forming an opening that exposes the conductive region.

17. The method of claim 15 wherein the further dielectric layer is a dielectric antireflective coating (DARC) layer.

18. The method of claim 15 wherein the moisture-removal step comprises a vacuum bake, ultraviolet light curing or hot plate curing.

19. The method of claim 15 wherein the moisture-removal step comprises a plasma treatment that takes place in the same reaction chamber further used for at least one of the forming a low-K dielectric layer and the forming a further dielectric layer.

20. The method of claim 15 wherein the moisture-removal step is a plasma treatment operation that includes at least one of argon, helium and a further inert gas.
